(19) United States
(12) Patent Application Publication
(10) Pub. No.: US 2025/0203774 A1
(43) Pub. Date: Jun. 19, 2025

(54) PRINTED CIRCUIT BOARD

(71) Applicant: SAMSUNG ELECTRO-MECHANICS CO., LTD., Suwon-si (KR)

(72) Inventors: Deok Hong JO, Suwon-si (KR); Jong Eun PARK, Suwon-si (KR); Chang Hwa PARK, Suwon-si (KR); Sang Ho JEONG, Suwon-si (KR); Hyun Hu LEE, Suwon-si (KR); Sang Won HAN, Suwon-si (KR)

(73) Assignee: SAMSUNG ELECTRO-MECHANICS CO., LTD., Suwon-si (KR)

(21) Appl. No.: 18/944,673

(22) Filed: Nov. 12, 2024

(30) Foreign Application Priority Data
Dec. 13, 2023 (KR) 10-2023-0180251

(51) Int. Cl. H05K 1/11

(52) U.S. Cl. CPC H05K 1/112; H05K 2201/0367; H05K 2201/096

(57) ABSTRACT

A printed circuit board includes a first insulating layer; a first metal layer having a part protruding beyond the first insulating layer and another part buried in the first insulating layer; and a barrier layer disposed on the first insulating layer. The barrier layer includes an inorganic oxide film.

CROSS-REFERENCE TO RELATED APPLICATION(S)

This application claims benefit of priority to Korean Patent Application No. 10-2023-0180251 filed on Dec. 13, 2023 in the Korean Intellectual Property Office, the disclosure of which is incorporated herein by reference in its entirety.

### TECHNICAL FIELD

The present disclosure relates to a printed circuit board.

There is an increasing need to implement a lighter and smaller printed circuit board on which a mobile device is mounted to respond to a recent trend of the lighter and smaller mobile device. In addition, there is a rapidly increasing need also for a high-density circuit that connects a logic semiconductor and a memory semiconductor to each other, or a logic semiconductor and a logic semiconductor to each other in accordance with an increasing demand for a high-performance printed circuit board for a server. Research has been continuously conducted to implement a printed circuit board having improved reliability in its connection with an electronic component such as a semiconductor chip including a high-density microcircuit and improved reliability in its connection with a main board.

### SUMMARY

An aspect of the present disclosure is to provide a printed circuit board that may be connected to an electronic component including a high-density microcircuit.

Another aspect of the present disclosure is to provide a printed circuit board where a microcircuit-implementation structure protrudes to the outermost side.

Still another aspect of the present disclosure is to provide a printed circuit board having improved reliability.

According to an aspect of the present disclosure, a printed circuit board includes: a first insulating layer; a first metal layer having a part protruding beyond the first insulating layer and another part buried in the first insulating layer; and a barrier layer disposed on the first insulating layer. The barrier layer includes an inorganic oxide film.

According to another aspect of the present disclosure, a printed circuit board includes: a first insulating layer; and a first metal layer having a protruding part protruding beyond the first insulating layer, a buried part buried in the first insulating layer, and a protrusion protruding outwards with respect to a side surface of the buried part and a side surface of the protruding part where the protrusion is in contact with the buried part and the protruding part. The protruding part, the buried part, and the protrusion are formed integrally with one another.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically showing an example of an electronic device system;

FIG. 2 is a perspective view schematically showing an electronic device according to an exemplary embodiment;

FIG. 3 is a cross-sectional view schematically showing a printed circuit board according to an exemplary embodiment;

FIG. 4 is a cross-sectional view schematically showing a printed circuit board according to another exemplary embodiment;

FIGS. 5 through 15 are cross-sectional views schematically showing a manufacturing method of a printed circuit board according to still another exemplary embodiment.

### DETAILED DESCRIPTION

Hereinafter, the present disclosure is described with reference to the accompanying drawings. In the accompanying drawings, shapes, sizes, and the like of components may be exaggerated or reduced for clarity.

### Electronic Device

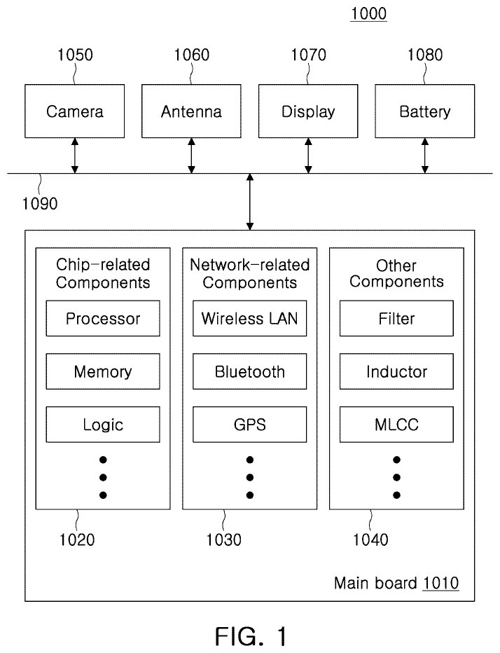

FIG. 1 is a block diagram schematically showing an example of an electronic device system.

Referring to the drawing, an electronic device 1000 may accommodate a main board 1010. Chip-related components 1020, network-related components 1030, other components 1040, or the like may be physically and/or electrically connected to the main board 1010. These components may be coupled to other electronic components described below to form various signal lines 1090.

The chip-related components 1020 may include a memory chip such as a volatile memory (for example, a dynamic random access memory (DRAM)), a non-volatile memory (for example, a read only memory (ROM)), or a flash memory; an application processor chip such as a central processor (for example, a central processing unit (CPU)), a graphics processor (for example, a graphics processing unit (GPU)), a digital signal processor, a cryptographic processor, a microprocessor, or a microcontroller; and a logic chip such as an analog-to-digital (ADC) converter or an application-specific integrated circuit (ASIC). However, the chip-related components 1020 are not limited thereto, and may also include other type of chip-related components. In addition, the chip-related components 1020 may be combined with each other. The chip-related components 1020 may be a package including the above-mentioned chip or electronic component.

The network-related components 1030 may include a protocol such as wireless fidelity (WiFi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, or 5G protocol, and any other wireless and wired protocols designated after the above-mentioned protocols. However, the network-related components 1030 are not limited thereto, and may also include any of various other wireless or wired standards or protocols. In addition, the network-related components 1030 may be combined with the chip-related components 1020.

Other components 1040 may include a high frequency inductor, a ferrite inductor, a power inductor, ferrite beads, low temperature co-firing ceramics (LTCC), an electro magnetic interference (EMI) filter, a multi-layer ceramic condenser (MLCC), and the like. However, other components 1040 are not limited thereto, and may further include a passive element or the like, in a form of a chip component used for various other purposes in addition to the above-mentioned components. In addition, other components 1040 may be combined with the chip-related components 1020 and/or the network-related components 1030.

The electronic device 1000 may include another electronic component that may be or may not be physically and/or electrically connected to the main board 1010, based on a type of the electronic device 1000. An example of another electronic component may include a camera module 1050, an antenna module 1060, a display 1070, a battery 1080, or the like. However, another electronic component is not limited thereto, and may be an audio codec, a video codec, a power amplifier, a compass, an accelerometer, a gyroscope, a speaker, a mass storage device (e.g., hard disk drive), a compact disk (CD), a digital versatile disk (DVD), or the like. In addition, another electronic component may include another electronic component used for various purposes, based on the type of the electronic device 1000.

The electronic device 1000 may be a smartphone, a personal digital assistant (PDA), a digital video camera, a digital still camera, a network system, a computer, a monitor, a tablet personal computer (PC), a laptop PC, a netbook PC, a television, a video game machine, a smartwatch, an automotive, or the like. However, the electronic device 1000 is not limited thereto, and may also be any other electronic device that processes data.

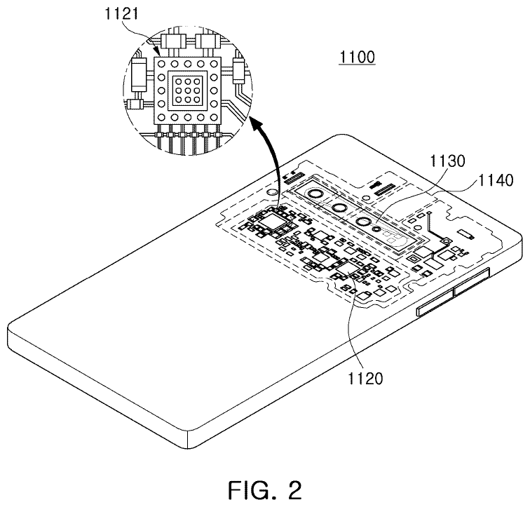

FIG. 2 is a perspective view schematically showing the electronic device according to an exemplary embodiment.

Referring to the drawing, the electronic device may be, for example, a smartphone 1100. The smartphone 1100 may accommodate a motherboard 1110, and various components 1120 may be physically and/or electrically connected to the motherboard 1110. In addition, the motherboard 1110 may accommodate another component that may be or may not be physically and/or electrically connected thereto, such as a camera module 1130 and/or a speaker 1140. Some of the components 1120 may be the chip-related components, for example, a component package 1121, and are not limited thereto. The component package 1121 may have the form of a printed circuit board on which the electronic component including an active component or a passive component is surface mounted. Alternatively, the component package 1121 may have the form of a printed circuit board in which the active component or the passive component is embedded. Meanwhile, the electronic device is not necessarily limited to the smartphone 1100, and may be another electronic device as described above.

### Printed Circuit Board

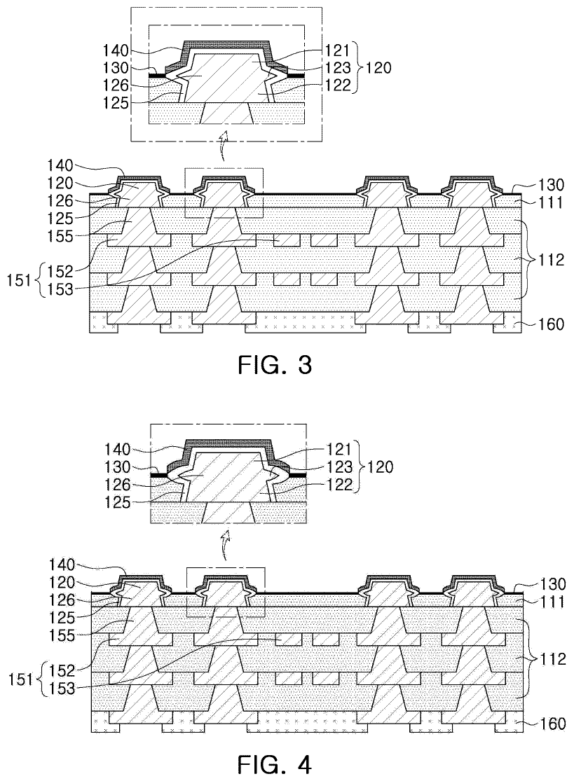

FIG. 3 is a cross-sectional view schematically showing a printed circuit board according to an exemplary embodiment.

Referring to FIG. 3, the printed circuit board according to an exemplary embodiment may include: a first insulating layer 111, a first metal layer 120 including a protruding part 121 protruding from the first insulating layer 111 and a buried part 122 buried in the first insulating layer 111, and a barrier layer 130 disposed in the first insulating layer 111, and the barrier layer 130 may include an inorganic oxide film. In addition, in the printed circuit board according to an exemplary embodiment, the first metal layer 120 may have a protrusion 123 protruding toward its outer peripheral surface.

The first insulating layer 111 may include an insulating material. The

insulating material may include a thermosetting resin such as an epoxy resin, a thermoplastic resin such as polyimide, or a material including an inorganic filler, an organic filler, and/or a glass fiber (i.e., glass fiber, glass cloth or glass fabric) together with this resin. The insulating material may be a photosensitive material and/or a non-photosensitive material. For example, the insulating material of the first insulating layer 111 may be an insulating material of Ajinomoto build-up film (ABF), is not limited thereto, and may include prepreg (PPG), resin coated copper (RCC), photo imageable dielectric (PID), FR-4, bismaleimide triazine (BT), or the like. However, the insulating material is not limited thereto, and may use another material having excellent rigidity if necessary.

The printed circuit board according to an exemplary embodiment may have a so-called coreless structure, and the first insulating layer 111 may be disposed on the outermost side of the printed circuit board according to an exemplary embodiment. In more detail, the first insulating layer 111 may be disposed on the uppermost side of the printed circuit board, and function as a post for connecting the first metal layer 120, implemented in the first insulating layer 111, with the electronic component such as a semiconductor chip.

The first metal layer 120 may include a metal material. The metal material may use copper (Cu), aluminum (Al), silver (Ag), tin (Sn), gold (Au), lead (Pb), titanium (Ti), or an alloy thereof. The metal material may include copper (Cu), and is not limited thereto. The first metal layer 120 may be a region for mounting the electronic component and the semiconductor chip, may be a region for its connection to the main board or the like, and may be connected to a circuit pattern to perform a signal connection with another pad. The first metal layer 120 may include a plurality of metal posts, is not limited thereto, and may further include a plurality of patterns and/or pads. Each metal post or pattern/pad of the first metal layer 120 may perform various functions based on a design. For example, the metal post or pattern/pad may include a ground pattern/pad, a power pattern/pad, a signal pattern/pad, or the like. Here, the signal pattern/pad may include pads/patterns for electrical connection of various signals other than ground signals and power signals, or the like, for example, data signals. In addition, the pattern/pad of the first metal layer 120 may electrically exchange a signal with another pattern/pad, and also perform a function by being electrically short-circuited with another pattern/pad.

Each gap between the metal posts and/or patterns of the first metal layer 120 may be narrowed in a case where the first metal layer 120 requires high density and fine pitch for mounting the electronic component such as the semiconductor chip on the first metal layer 120. The gap of the first metal layer 120 may be wider, and a height of the first metal layer 120 may be lower in case of mounting the electronic components such as the passive component on the first metal layer 120.

The first metal layer 120 may be formed using any of a semi additive process (SAP), a modified semi additive process (MSAP), a tenting (TT) method, or a subtractive method, and is not limited thereto. As a non-limiting example, a method of forming the first metal layer 120 may include forming the first metal layer 120 by performing electroless copper plating (chemical copper) followed by electroplating (electrical copper), forming the first metal layer 120 by firing a paste including the metal material, or the like. The method is not limited thereto, and may further include a configuration or a method, which may be used by those skilled in the art. As a non-limiting example, each first metal layer 120 may include a seed layer 125 and a plating layer 126.

The seed layer 125 may be disposed on the outermost side of the first metal layer 120, and disposed along the upper side and side surface of the first metal layer 120. The seed layer 125 may be a result of forming the seed layer 125 along a wall of a through hole formed in a temporary layer or the first insulating layer 111. The seed layer 125 may function as a seed to form the plating layer 126. The seed layer 125 may include the electroless plating layer (or chemical copper) formed through electroless plating, and is not limited thereto. The seed layer 125 may include a sputtering layer formed by sputtering instead of the electroless plating, and include both the electroless plating layer and the sputtering layer. The seed layer 125 is not limited thereto, and may use any metal that may function as a seed for the electroplating, such as a copper foil, without limitation, if necessary.

The plating layer 126 may be disposed on the seed layer 125, and may be formed using the seed layer 125 as a plating seed. The plating layer 126 may fill the through hole formed in the temporary layer or the first insulating layer 111, and be formed on the seed layer 125 formed on an inner wall of the through hole. Therefore, the plating layer 126 may be disposed on the seed layer 125, and formed inward or downward from the printed circuit board. The plating layer 126 may include an electroplating layer (or electroplating) formed through electroplating. However, the plating layer 126 is not limited thereto, and may be formed by firing a paste including the metal material. As such, the plating layer 126 may not necessarily be formed by plating. That is, the plating layer 126 is only intended to express the fact that the plating layer 126 is a separate metal layer that may be distinguished from the seed layer 125, a method of forming the plating layer 126 is not necessarily limited by the text itself, and may further include a configuration or a method, which may be used by those skilled in the art.

The first metal layer 120 may function to connect the printed circuit board to the electronic component such as the semiconductor chip, or to another component such as the main board. In particular, the first metal layer 120 may include the protruding part 121 protruding upward from the first insulating layer 111 to thus perform its connection with the electronic component having the fine pitch more smoothly, and prevent a defect caused by the short circuit or separation of a connecting member in case of forming an electrical connection path. In the printed circuit board according to an exemplary embodiment, the protruding part 121 of the first metal layer 120 may be formed by forming the through hole to pass through the first insulating layer 111, the barrier layer 130, and the temporary layer, forming the first metal layer 120 to fill the through hole, and then removing the temporary layer, thus allowing the protruding part of the first metal layer 120 to have a certain height.

The printed circuit board according to an exemplary embodiment may be a so-called coreless board, and a portion of the first metal layer 120 disposed on the uppermost side of the board may be buried in the first insulating layer 111. However, in a process of forming the first metal layer 120, the temporary layer and the barrier layer 130 may be formed first, and then the first insulating layer 111 may be formed. Therefore, although the printed circuit board according to an exemplary embodiment is the coreless board, the protruding part 121 of the first metal layer 120 may protrude beyond the first insulating layer 111.

The first metal layer 120 may include the buried part 122 buried in the first insulating layer 111, together with the protruding part 121 protruding upward from the first insulating layer 111. The buried part 122 may be a part that passes through the upper and lower surfaces of the first insulating layer 111, and correspond to a region disposed in the first insulating layer 111. A side surface of the buried part 122 may be covered by the first insulating layer 111.

Meanwhile, the first metal layer 120 may include the protrusion 123 together with the protruding part 121 and the buried part 122. The protrusion 123 may correspond to a plating foot of the first metal layer 120 that protrudes toward the outer peripheral surface of the first metal layer 120. The protrusion 123 may be formed across the protruding part 121 and buried part 122 of the first metal layer 120. A lower side of the protrusion 123 may be in contact with the first insulating layer 111, and an upper side of the protrusion 123 may be exposed from the first insulating layer 111 rather than being covered by the first insulating layer 111. The protrusion 123 may have a portion disposed in the first insulating layer 111, and the other portion protruding more than the first insulating layer 111.

The protrusion 123 may be a result of the first metal layer 120 filling a groove occurring when removing a portion of the barrier layer 130. The protrusion 123 may be the result of forming the groove by removing a portion of the temporary layer disposed on the barrier layer 130 and a portion of the first insulating layer 111 disposed below the barrier layer 130 while removing a portion of the barrier layer 130 in a process of removing a portion of the barrier layer 130 that is exposed to the inner wall of the through hole after forming the through hole passing through the temporary layer, the barrier layer 130, and the first insulating layer 111, and then forming the first metal layer 120 to fill the groove in the process of forming the first metal layer 120.

In the printed circuit board according to an exemplary embodiment, the first metal layer 120 may include the protrusion 123 to thus provide a wider area where the first metal layer 120 is in contact with the first insulating layer 111 to be wider, and the protrusion 123 may be disposed on an upper surface of the first insulating layer 111 to generate an anchoring effect, or the like, thereby increasing adhesion and coupling strength between the first metal layer 120 and the first insulating layer 111. The first metal layer 120, which is connected to the electronic component such as the semiconductor chip, may be stably coupled with the first insulating layer 111, and the printed circuit board according to an exemplary embodiment may have improved connection reliability.

The protrusion 123 may have a ring shape to correspond to the shape of the first metal layer 120, and is not necessarily limited thereto. As a non-limiting example, the protrusion 123 may have a width at the center that is wider than a width at its upper and/or lower sides. The width of the protrusion may be measured by capturing a cut cross section of the printed circuit board in a stacking direction by using a scanning microscope or the like. The fact that the width of the protrusion 123 at the center may be wider than its width at the upper side and/or the lower side may indicate that a middle region may have a more convex shape than the upper and lower sides in the cut cross section of the printed circuit board. FIG. 3 shows that the protrusion 123 has a trapezoid-like shape, not limited thereto, and may have a curved surface or an uneven surface. In addition, the shape of the protrusion 123 is not limited to that shown in FIG. 3, and may not be vertically symmetrical with respect to the surface on which the barrier layer 130 is formed, which may be caused by a difference in a removal level of the temporary layer and that of the first insulating layer 111 in the process of forming the groove.

The seed layer 125 of the first metal layer 120 may extend along the outside of the protrusion 123. That is, the seed layer 125 may be disposed on the outside of the first metal layer 120, and extend along the protruding part 121, the protrusion 123, and the buried part 122. The seed layer 125 may be disposed along the inner walls of the through hole and the groove, and the plating layer 126 may be formed on the seed layer 125. Therefore, the seed layer 125 may be disposed on the outermost side of the first metal layer 120. Here, the seed layer 125 may be thinner than the groove. Therefore, the seed layer 125 may be disposed conformally along the inside of the groove and along boundaries of the first insulating layer 111 and the temporary layer.

Meanwhile, it is not always possible to clearly distinguish the boundaries of

the protruding part 121, the buried part 122, and the protrusion 123 of the first metal layer 120. The boundary is a concept for distinction based on the position and shape, the first metal layer 120 may be integrally formed, thus making the boundaries of the protruding part 121, the buried part 122, and the protrusion 123 unclear. That is, the seed layer 125 disposed on the outside of the protruding part 121 may extend along the outside of the protrusion 123 to externally extend from the buried part 122, and the seed layers 125 disposed in the respective regions may be integrated with each other. In addition, the plating layer 126 disposed on the protruding part 121 may also extend to the protrusion 123 and the buried part 122, and the plating layers 126 disposed in the respective regions may also be integrally formed.

The first metal layer 120 may have a shape tapered upward, and each of the protruding part 121 and the buried part 122 may have a shape tapered upward. The fact that the first metal layer 120 has the shape tapered upward may indicate that the first metal layer 120 has a substantially tapered shape for an upper width of the protruding part 121 of the first metal layer 120 to be narrower than a lower width of the buried part 122 of the first metal layer 120. The first metal layer 120 may be formed to fill the through hole passing through the temporary layer and first insulating layer 111. Therefore, the first metal layer 120 may have the same shape as that of the through hole. A process of forming the through hole passing through the temporary layer and the first insulating layer 111 may be vertically performed. Therefore, the upper width, which is a bottom surface of the through hole, may be narrower than the lower width, which is an opening, and may have the tapered shape. However, the lower width and the upper width are not necessarily limited thereto, and may be substantially the same as each other for the first metal layer 120 to have a non-tapered shape.

That is, the first metal layer 120 may have the shape tapered upward. Here, the protruding part 121 and the buried part 122 may be tapered in substantially the same direction as each other. The printed circuit board according to an exemplary embodiment may have a coreless structure, and the first metal layer 120 may fill the through hole passing through the temporary layer and the first insulating layer 111. Therefore, the first metal layer 120 may have the shape tapered upward.

The barrier layer 130 may be disposed on the first insulating layer 111, and may be used to separate the temporary layer and the first insulating layer 111 from each other, as described below in the manufacturing method. After forming the temporary layer, the barrier layer 130 may be formed and the first insulating layer 111 may be formed, and a release layer may thus be formed between the temporary layer and the first insulating layer 111. The protruding part 121 of the first metal layer 120 may be formed by removing the temporary layer disposed above the barrier layer 130. Here, even though the temporary layer and the first insulating layer 111 include substantially the same insulating material, the barrier layer 130 may be disposed between the temporary layer and the first insulating layer 111, thereby preventing the first insulating layer 111 from being damaged in the process of removing the temporary layer.

The barrier layer 130 may include a material substantially different from that of the first insulating layer 111. The barrier layer 130 may be a thin oxide film including metal oxide. The metal oxide may include at least one of aluminum oxide (Al₂O₃), silicon dioxide (SiO₂), titanium dioxide (TiO₂), zinc oxide (ZnO), zirconium dioxide (ZrO₂), hafnium dioxide (HfO₂), and lanthanum oxide (La₂O₃), and may also include the metal oxide doped with a different metal element. The metal oxide may include alumina (Al₂O₃). Meanwhile, a material of the barrier layer 130 is not necessarily limited to the metal oxide, and may include a metal material having low reactivity such as platinum (Pt) and ruthenium (Ru).

The barrier layer 130 may be formed using a thin film deposition method, such as an atomic layer deposition (ALD) method or a molecular vapor deposition (MVD) method. As the barrier layer 130 is formed using the thin film deposition method, the barrier layer 130 may include the oxide film that is thinner than the first insulating layer 111. As a non-limiting example, the barrier layer 130 may include the thin oxide film less than 0.1 μm thick, approximately 0.001 μm to 0.05 μm thick. The barrier layer 130 may be thinner than the first insulating layer 111 and also be thinner than the seed layer 125. Meanwhile, FIG. 3 shows that the barrier layer 130 has a similar thickness to that of the seed layer 125, and is not limited thereto. The seed layer 125 may be thicker than the barrier layer 130. As a non-limiting example, the seed layer 125 may include a plating layer less than 1 μm thick and about 0.1 μm to 0.5 μm thick.

The thickness of the barrier layer 130 may be measured by capturing the cut cross section of the printed circuit board in the stacking direction by using the scanning microscope or the like. For example, the thickness of the barrier layer 130 may be the average value of the barrier layer 130 in a vertical distance that is measured at five random points. This measurement method may also be applied to a thickness measurement method of the seed layer 125. The seed layer 125 may be disposed conformally along an outer surface of the first metal layer 120. Therefore, the thickness of the seed layer 125 may be interpreted as a distance across the outer and inner surfaces of the seed layer 125, and may include a measurement error or an error occurring in its manufacturing process.

As the barrier layer 130 may be formed using the thin film deposition method, and thus be disposed along the upper surface of the first insulating layer 111. In more detail, the first insulating layer 111 may be formed after forming the barrier layer 130 on the temporary layer. Therefore, the first insulating layer 111 may be stacked on barrier layer 130 after forming the barrier layer 130 along the temporary layer.

The barrier layer 130 may be in contact with a side of the first metal layer 120. In detail, the barrier layer 130 may be in contact with the protrusion of the first metal layer 120. This configuration may be a result of forming the protrusion 123 to fill the groove, which is a region where portions of the barrier layer 130 and the first insulating layer 111 are removed.

To form the protruding part on a conventional coreless board, a process of further forming the separate metal layer on the outermost buried pattern of the coreless board, or a process of removing a portion of the insulating layer disposed on the outermost side may be performed. In the printed circuit board according to an exemplary embodiment, the barrier layer 130 may be disposed on the first insulating layer 111. Accordingly, the protruding part 121 and buried part 122 of the first metal layer 120 may be integrated with each other, and the first insulating layer 111 may be protected by the barrier layer 130.

Therefore, the printed circuit board according to an exemplary embodiment may overcome an alignment problem of the protruding part having the fine pitch, and minimize an undercut defect, which is a defect that occurs at an interface between two metal layers. In addition, the printed circuit board according to an exemplary embodiment does not require the process of removing a portion of the first insulating layer 111. Therefore, the first insulating layer 111 may be protected in the process of removing the temporary layer. As a result, a defect such as a crevice occurring between the first metal layer 120 and the first insulating layer 111, may not occur that occurs in a protruding relationship between the outermost insulating layer and the first metal layer 120.

That is, unlike the conventional method of performing a plurality of plating to have the coreless structure and the protruding structure, the present disclosure has a structural feature that is achieved by forming the protruding part using one plating, and may avoid problems such as misalignment and deviation that occur between the protruding part and the buried part, by having this structure.

In addition, unlike the conventional method of performing the process of removing a portion of the insulating layer to have the coreless structure and the protruding structure, the present disclosure has a structural feature achieved by forming the through hole and the groove in the insulating layer, then forming the metal layer using one plating to fill the same, and easily removing the temporary layer above the barrier layer 130, and may thus be prevented from problems such as crevices, depressions, or cracks that occur near the boundary between the metal layer and the insulating layer, by having this structure.

The printed circuit board according to an exemplary embodiment may further include: a second insulating layer 112 disposed below the first insulating layer 111, a first wiring layer 151 disposed on the second insulating layer 112, and a first via layer 155 passing through at least a portion of the second insulating layer 112 to connect the first wiring layer 151 and the first metal layer 120 to each other or connect the first wiring layers 151 to each other.

The second insulating layer 112 may include an insulating material. The insulating material may include the thermosetting resin such as an epoxy resin or a thermoplastic resin such as polyimide, or a material including an inorganic filler, an organic filler, and/or a glass fiber (i.e., glass fiber, glass cloth or glass fabric) together with the resin. The insulating material may be a photosensitive material and/or a non-photosensitive material. For example, the insulating material of the second insulating layer 112 may be an insulating material of Ajinomoto build-up film (ABF), is not limited thereto, and may include prepreg (PPG), resin coated copper (RCC), photo imageable dielectric (PID), FR-4, bismaleimide triazine (BT), or the like. However, the insulating material is not limited thereto, and may use another material having excellent rigidity if necessary. The second insulating layer 112 may include substantially the same type of insulating material as the first insulating layer 111. That is, the first insulating layer 111 may be a build-up insulating layer like the second insulating layer 112.

The first insulating layer 111 may be thinner than the second insulating layer 112. The first metal layer 120 is required to be able to make fine connections, and it is thus advantageous for the first metal layer 120 to include thin and fine pads and posts. Therefore, in order to pass through the top and bottom of the first insulating layer 111, the first insulating layer 111 may be implemented to be thinner than the second insulating layer 112, which is a general build-up layer. Meanwhile, a thickness relationship between the first insulating layer 111 and the second insulating layer 112 is not necessarily limited thereto, and the thickness of the first insulating layer 111 and the thickness of the second insulating layer 112 may be designed in various ways based on their needs. The thickness of the insulating layer may be measured by capturing the cut cross section of the printed circuit board in the stacking direction by using the scanning microscope or the like, may be the average value of the insulating layer in the vertical distance measured from five random points, is not necessarily limited thereto, and it is sufficient to compare the thicknesses of the first insulating layer 111 with the second insulating layer 112 by using the same thickness measurement method.

Meanwhile, the second insulating layer 112 may include a plurality of insulating layers, and the number and thickness of the layers may use any configuration available to those skilled in the art.

The first wiring layer 151 may include a metal material. The metal material may use copper (Cu), aluminum (Al), silver (Ag), tin (Sn), gold (Au), lead (Pb), titanium (Ti), or an alloy thereof. The metal material may include copper (Cu), and is not limited thereto. The first wiring layer 151 may include each of an electroless plating layer (or chemical copper) and an electrolytic plating layer (or electroplating), and is not limited thereto. The first wiring layer 151 may include a sputtering layer instead of the electroless plating layer, or include both the layers. In addition, the first wiring layer 151 may further include a copper foil.

The first wiring layer 151 may include a plurality of pads/patterns, and perform various functions based on each design. For example, the first wiring layer 151 may include a ground pattern/pad, a power pattern/pad, a signal pattern/pad, or the like. Here, the signal pattern/pad may include pads/patterns for the electrical connection of the various signals other than the ground signals and the power signals, or the like, for example, the data signals.

As a non-limiting example, the first wiring layer 151 may include a first pad 152 and a first pattern 153. The first pad 152 may refer to a configuration connected to the first via layer 155, the first pattern 153 may be a wiring connecting the first pads 152, is not limited thereto, and may be a pattern of various shapes.

The first pad 152 of the first wiring layer 151 may have a width wider than a distance between both ends of the protrusion 123 of the first metal layer 120. That is, a width between both the ends of the protrusion 123 of the first metal layer 120 may be narrower than the width of the first pad 152 of the first wiring layer 151. The width of the first pad 152 and the width between both the ends of the protrusion 123 of the first metal layer 120 may be measured by capturing the cut cross section of the printed circuit board in the stacking direction by using the scanning microscope or the like. The first wiring layer 151 may be a build-up wiring layer that is disposed in the printed circuit board. On the other hand, the first metal layer 120 may be disposed on the outermost side of the printed circuit board, and connected to the electronic component such as the semiconductor chip. Therefore, the first metal layer 120 may be finer than the first wiring layer 151. In particular, the width of both the ends of the protrusion 123 of the first metal layer 120 may correspond to the longest width of the first metal layer 120. Therefore, when the width of the first metal layer 120 is larger than the width of the first pad 152, it is not only advantageous in coupling the first metal layer 120 with the electronic component having a fine structure, but also increases a possibility of causing a short circuit defect due to solder or the like. Therefore, it may be more advantageous for the connection reliability when the width between both the ends of the protrusion 123 of the first metal layer 120 is formed to be smaller than the first pad 152 of the first wiring layer 151.

The first via layer 155 may each include a micro via. The micro via may be a filled via that fills a via hole or a conformal via that is disposed along a wall surface of the via hole. The micro vias may be disposed in a stacked type or a staggered type. The first via layer 155 may each include a metal, the metal may include copper (Cu), aluminum (Al), silver (Ag), tin (Sn), gold (Au), nickel (Ni), lead (Pb), titanium (Ti), or an alloy thereof, may include copper (Cu), and is not limited thereto. The first via layer 155 may include each of the electroless plating layer (or chemical copper) and the electrolytic plating layer (or electroplating), and is not limited thereto. The first via layer 155 may include the sputtering layer instead of the electroless plating layer, or include both the layers. The first via layers 155 may perform various functions based on the respective designs of the corresponding layers. For example, the first via layers 155 may include a ground via, a power via, a signal via, or the like.

Meanwhile, the number of layers included in the second insulating layer 112 may be various. Accordingly, the first wiring layer 151 disposed on the second insulating layer 112 and the first via layer 155 passing through at least part of the second insulating layer 112 may also have various numbers of layers.

Meanwhile, the printed circuit board according to an exemplary embodiment may further include a solder resist layer 160 disposed below the second insulating layer 112. That is, the printed circuit board according to an exemplary embodiment may further include the solder resist layer 160 on the lowermost side. The solder resist layer 160 may include an insulating material, may include a liquid or film type solder resist, is not limited thereto, and may use another type of insulating material. The solder resist layer 160 may have an opening exposing at least a portion of the first wiring layer 151. A portion of the first wiring layer 151 exposed through the opening may subsequently function as a pad to be connected to another component such as the main board, and is not necessarily limited thereto.

The printed circuit board according to an exemplary embodiment may further include a surface treatment layer 140 disposed on the first metal layer 120. The surface treatment layer 140 may be disposed on the first metal layer 120, and cover a region of the first metal layer 120 that is exposed from the first insulating layer 111. That is, the surface treatment layer 140 may cover the protruding part 121 of the first metal layer 120 and the top of the protrusion 123.

The surface treatment layer 140 may include any one of nickel (Ni), palladium (Pd), and gold (Au), and may be implemented as the plurality of metal layers. For example, the surface treatment layer 140 may be at least a portion of an electroless nickel electroless palladium immersion gold (ENEPIG) structure, and may be at least a portion of an electroless nickel immersion gold (ENIG) structure. The surface treatment layer 140 is not limited thereto, and may include an organic solder passivation (OSP) structure that includes an organic material. The surface treatment layer 140 may improve the adhesion and signal transmission between the first metal layer 120 and a connection member such as solder. FIG. 3 shows that the surface treatment layer 140 includes one layer, is not limited thereto, and the surface treatment layer 140 may be implemented as the plurality of metal layers as described above.

The surface treatment layer 140 may be thicker than the barrier layer 130. The barrier layer 130 may be the oxide film by the surface deposition as described above. However, the surface treatment layer 140 may be a plating layer by the electroless plating and may include the plurality of metal layers. Therefore, the surface treatment layer 140 may be thicker than the barrier layer 130 including the thin oxide film.

Meanwhile, the printed circuit board according to an exemplary embodiment is not limited to the configuration shown in FIG. 3, may further include another configuration, or omit some configurations in some cases. That is, the printed circuit board according to an exemplary embodiment may further include a configuration available to those skilled in the art.

FIG. 4 is a cross-sectional view schematically showing a printed circuit board according to another exemplary embodiment.

Referring to FIG. 4, in the printed circuit board according to another exemplary embodiment, the protrusion 123 of the first metal layer 120 may have a round end shape. This shape may be a result of wider penetration of an etching solution in the process of forming the groove by removing portions of the barrier layer 130 and the first insulating layer 111. The protrusion 123 may have the round end shape, and the first metal layer 120 of the printed circuit board according to another exemplary embodiment may thus increase its contact area with the first insulating layer 111.

Meanwhile, among the configurations other than the shape of the first metal layer 120, the same configuration as that of the printed circuit board according to an exemplary embodiment may also be applied to the printed circuit board according to another exemplary embodiment, and the description thus omits its redundant description.

### Manufacturing Method of Printed Circuit Board

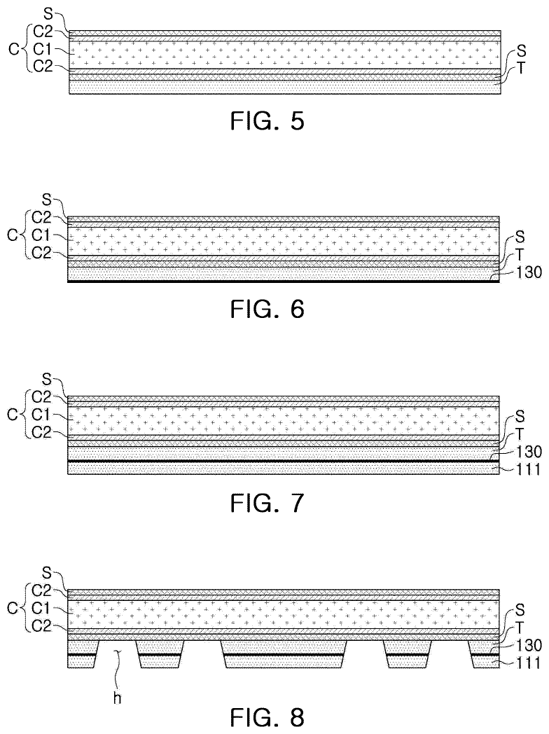

FIGS. 5 through 15 are cross-sectional views schematically showing a manufacturing method of a printed circuit board according to still another exemplary embodiment.

The manufacturing method of a printed circuit board according to another exemplary embodiment may include: a process of forming a temporary layer T on a carrier board C; a process of forming a barrier layer 130 on the temporary layer T; a process of forming a first insulating layer 111 on the barrier layer 130; a process of forming a through hole h passing through the first insulating layer 111, the barrier layer 130, and the temporary layer T; a process of forming a groove g by removing portions of the barrier layer 130, the first insulating layer 111, and the temporary layer T; a process of forming the first metal layer 120 to fill the through hole h and the groove g; and a process of removing the carrier board C and the temporary layer T.

In the manufacturing method of a printed circuit board according to another exemplary embodiment, the first insulating layer 111 may be formed after forming the barrier layer 130 on the temporary layer T, thereby preventing the first insulating layer 111 from being damaged in the process of removing the temporary layer T. In particular, even though the temporary layer T and the first insulating layer 111 include substantially the same insulating material, the first insulating layer 111 may not be damaged in the process of removing the temporary layer T. In addition, the first metal layer 120 may be formed after forming the through hole h and the groove g, and the protruding part 121, buried part 122, and protrusion 123 of the first metal layer 120 may thus be formed integrally with one another.

Referring to FIG. 5, the manufacturing method of a printed circuit board may include the process of forming the temporary layer T on the carrier board C. In addition, the method may further include forming a stopper layer S on the carrier board C before the process of forming the temporary layer T on the carrier board C. In this case, the temporary layer T may be disposed on the stopper layer S.

The carrier board C may be intended to support an insulating layer and a wiring layer when forming the same, and may be made of an insulating material or a metal material. FIG. 5 shows that the carrier board C includes a core C1 and a seed C2 formed on each of two sides of the core C1, and is not limited thereto. The carrier board C may include one layer, or the seed C2 may include a double layer. That is, the carrier board C shows an example, the carrier board C may be used by those skilled in the art, and the carrier board C may be used without particular limitation in the present disclosure as long as the carrier board C is used as a support board and may be subsequently detached or removed.

The method may further include the forming of the stopper layer S on the carrier board C before the process of forming the temporary layer T. The stopper layer S may later perform a function of separating the carrier board C and the first metal layer 120 from each other. The stopper layer S may include a metal material, and the metal material may use nickel (Ni), aluminum (Al), tin (Sn), gold (Au), lead (Pb), titanium (Ti), or an alloy thereof. The stopper layer S may include nickel (Ni), and is not limited thereto. The stopper layer S is required to be separated from the temporary layer T and the first metal layer 120 in a subsequent detaching process. Therefore, it is sufficient for the stopper layer S to be made of a different metal material from that of the temporary layer T. The stopper layer S may use any material that may easily separate the first metal layer 120 from the carrier board C in the process of removing the carrier board C without any particular limitation.

The temporary layer T may be a temporary configuration for forming the protruding part 121 of the first metal layer 120, and may be a temporary configuration that is disposed on the carrier board C and removed after forming the first metal layer 120.

The temporary layer T may include an insulating material. The insulating material may include a thermosetting resin such as an epoxy resin or a thermoplastic resin such as polyimide, or a material including an inorganic filler, an organic filler, and/or a glass fiber (i.e., glass fiber, glass cloth or glass fabric) together with this resin. The insulating material may be a photosensitive material and/or a non-photosensitive material. For example, the insulating material may be an insulating material of Ajinomoto build-up film (ABF), is not limited thereto, and may include prepreg (PPG), resin coated copper (RCC), photo imageable dielectric (PID), FR-4, bismaleimide triazine (BT), or the like. However, the insulating material is not limited thereto, and may use another material having excellent rigidity if necessary. The temporary layer T may include substantially the same type of insulating material as the first insulating layer 111. Even though the temporary layer T includes substantially the same type of insulating material as the first insulating layer 111, the barrier layer 130 may be formed in a subsequent process. Therefore, the temporary layer T may be easily separated from the first insulating layer 111, and the first insulating layer 111 may not be damaged.

Meanwhile, the temporary layer T is not limited thereto, and may include the metal material rather than including the insulating material. In this case, the temporary layer T may include a material different from the metal material of the first metal layer 120, and the first metal layer 120 may not react in the process of removing the temporary layer T.

Referring to FIG. 6, the manufacturing method of a printed circuit board may include the process of forming the barrier layer 130 on the temporary layer T.

The barrier layer 130 may be formed using a thin film deposition method, such as an atomic layer deposition (ALD) method or a molecular vapor deposition (MVD) method. As the barrier layer 130 is formed using the thin film deposition method, the barrier layer 130 may include the oxide film that is thinner than the temporary layer T and the first insulating layer 111. The method of forming the barrier layer 130 may be the deposition method, and the barrier layer 130 may be formed to be thin along a lower surface of the temporary layer T.

The barrier layer 130 may include the material different from the temporary layer T and the first insulating layer 111. Therefore, the temporary layer T may be removed more smoothly while protecting the first insulating layer 111 in the process of removing the temporary layer T after the process of forming the first metal layer 120.

Referring to FIG. 7, the manufacturing method of a printed circuit board may include the process of forming the first insulating layer 111 on the barrier layer 130.

A description of the first insulating layer 111 is the same as its description provided in describing the printed circuit board above, and the method of forming the first insulating layer 111 may use any method that is a known method of forming the insulating layer, which may be used by those skilled in the art, without limitation.

Referring to FIG. 8, the manufacturing method of a printed circuit board may include the process of forming the through hole h passing through the first insulating layer 111, the barrier layer 130, and the temporary layer T. The method of forming the through hole h may use any method that may process to pass through the first insulating layer 111 and the temporary layer T without limitation. As a non-limiting example, the method may be performed by laser drilling, mechanical drilling, or the like, is not limited thereto, and use any method that may pass through the insulating layer without limitation. Meanwhile, when performing the laser drilling, the method may use a carbon dioxide (CO₂) laser or yttrium aluminum garnet (YAG) laser, and is not limited thereto.

Here, the through hole h may be formed through one processing, and is not limited thereto. The through hole h may also be formed by passing through the first insulating layer 111, then removing a portion of the barrier layer, and then passing through the temporary layer T. The through hole h may pass through the temporary layer T, the barrier layer 130, and the first insulating layer 111. Therefore, the stopper layer S may be exposed through the through hole h. The through hole h may be processed from bottom to top as shown in FIG. 8. Therefore, the through hole h may have a shape tapered upward. Meanwhile, a tapering level of the through hole h may be determined by processing methods and conditions.

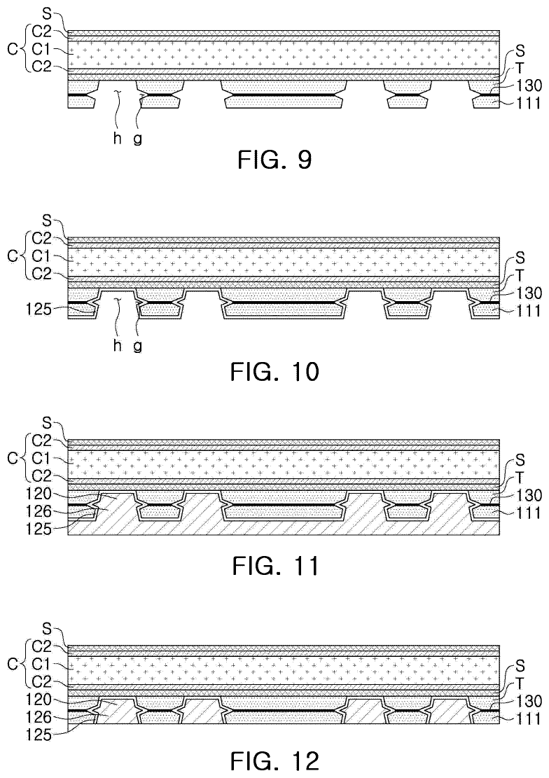

Referring to FIG. 9, the manufacturing method of a printed circuit board may include the process of forming the groove g. The process of forming the groove may be performed by a process of removing a portion of the barrier layer 130 that is exposed to the through hole h, portions of the first insulating layer 111 and the temporary layer T, adjacent to the barrier layer 130.

The groove g may be a region for forming the protrusion 123 of the first metal layer 120. Portions of the barrier layer 130, the first insulating layer 111, and the temporary layer T may be removed in a horizontal direction based on the through hole h or in a direction of an outer peripheral surface of the through hole h. The method of forming the groove g may be used without limitation as long as the method may remove a portion of the insulating material. As a non-limiting example, the process of processing the groove may include the process of removing a portion of the barrier layer 130 and performing desmear. The process of removing a portion of the barrier layer 130 may be performed by etching, and desmear is a method of removing residues occurring in the process of forming the through hole h, and may be performed by wet desmear. After the process of removing a portion of the barrier layer 130, the process of removing portions of the first insulating layer 111 and the temporary layer T may be performed as a wet process. Accordingly, the solution may be concentrated in a region where a portion of the barrier layer 130 is removed, and the groove g may thus be formed. As the groove g is formed, an area where the first metal layer 120 is in contact with the first insulating layer 111 may be wider, and an adhesion of the first metal layer 120 may thus be improved. In addition, a portion of the barrier layer 130 may be removed. Therefore, the adhesion between the temporary layer T and the barrier layer 130 may be reduced compared to before the groove g is formed. Therefore, the barrier layer 130 and the temporary layer T may then be more easily separated from each other, and the protruding part 121 of the first metal layer 120 may be easily formed in a subsequent process.

FIG. 10 shows that the groove g in a vertically cut cross section of the printed circuit board has a triangular or trapezoidal shape, and is not limited thereto. The shape of the groove g may depend on a solution penetration level. For example, the groove g may have a curved surface, or upper and lower sides asymmetrical to each other.

Referring to FIG. 10, the manufacturing method of a printed circuit board may include the process of forming the first metal layer 120. The process of forming the first metal layer 120 may include a process of forming a seed layer 125 along the through hole h and the groove g.

The seed layer 125 may be formed in the through hole h and the groove g, and may be disposed along the bottom of the first insulating layer 111. That is, the seed layer 125 may be formed conformally along the through hole h and the groove g. The seed layer 125 may configure the outermost side of the first metal layer 120, the process of forming the seed layer 125 may be performed by electroless plating, is not limited thereto, and also be performed by sputtering. Meanwhile, the process of forming the seed layer 125 is not limited thereto, and may use any method of forming the seed layer 125 for electroplating without limitation.

Referring to FIG. 11, the manufacturing method of a printed circuit board may include the process of forming the first metal layer 120. The process of forming the first metal layer 120 may include a process of forming a plating layer 126 on the seed layer 125.

The plating layer 126 may be disposed on the seed layer 125, and may be formed using the seed layer 125 as a plating seed. The plating layer 126 may be formed to fill the through hole h and the groove g, and may also be formed on the lower side of the first insulating layer 111. The plating layer 126 may be provided by the electroplating, and any method of forming the plating layer 126 may be used by those skilled in the art without particular limitation.

Referring to FIG. 12, the manufacturing method of a printed circuit board may include the process of forming the first metal layer 120. The process of forming the first metal layer 120 may include completing the first metal layer 120 by removing portions of the seed layer 125 and the plating layer 126.

The seed layer 125 may function as a plating lead-in line for the plating layer 126, and thus be formed over an entire lower surface of the first insulating layer 111. The plating layer 126 may be disposed on the seed layer 125 to thus fill both a first through hole h1 and a second through hole h2, and also be formed on the lower side of the first insulating layer 111. Accordingly, the seed layer 125 and the plating layer 126 may not be electrically connected to each other and may not perform their respective functions. Accordingly, portions of the seed layer 125 and the plating layer 126 may be removed to allow each of the first metal layers 120 to perform independent functions. Here, the process of removing a portion of the first metal layer 120 may be performed by etching, and is not limited thereto.

Meanwhile, referring to FIGS. 10 through 12, it is shown that the first metal layer 120 is formed by forming the seed layer 125 by the electroless plating and then forming the plating layer 126 by the electroplating, is not necessarily limited thereto, and the method of forming the first metal layer 120 may not be limited thereto. It is sufficient when the first metal layer 120 may be formed to fill the through hole h and the groove g. Any method of forming a metal layer may be used by those skilled in the art without particular limitation.

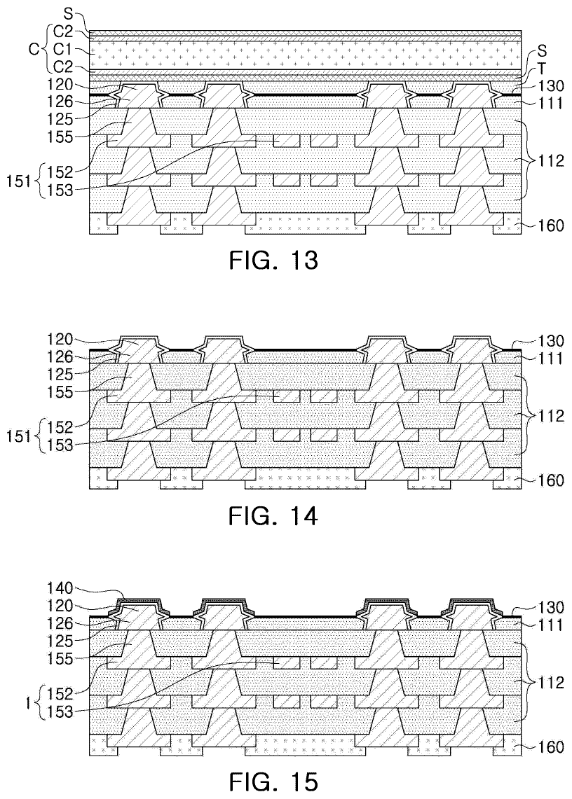

Referring to FIG. 13, the manufacturing method of a printed circuit board may include: a process of forming the second insulating layer 112 below the first insulating layer 111; a process of forming a first wiring layer 151 on the second insulating layer 112; and a process of forming a first via layer 155 passing through at least a portion of the second insulating layer 112 to connect the first metal layer 120 and the first wiring layer 151 to each other or to connect the first wiring layers 151 to each other. In addition, the method may further include a process of forming a solder resist layer 160 on the second insulating layer 112.

The method of forming the second insulating layer 112, the method of forming the first wiring layer 151 and the first via layer 155, and the method of forming the solder resist layer 160 may use any method of building-up the insulating layer and the wiring layer, which may be used by those skilled in the art, without limitation.

Referring to FIG. 14, the manufacturing method of a printed circuit board may include the process of removing the carrier board C, the process of removing the stopper layer S, and the process of removing the temporary layer T.

The process of removing the carrier board C may be performed in various ways based on a type of the carrier board C. For example, the process of removing the carrier board C may be sequentially performed by removing a copper foil after removing a core included in the carrier board, or removing the entire carrier board, that is, simultaneously removing the core and the copper foil. The process of removing the carrier board C may be performed using a known process used for detaching the carrier without limitation.

The process of removing the stopper layer S may be performed by the etching, and is not limited thereto. The process of removing the stopper layer S may be performed by different processes based on a material included in the stopper layer S, and use any process that may remove the material included in the stopper layer S without limitation. That is, different conditions may be implemented based on the material in the stopper layer S. The stopper layer S may include a metal different from that in the first metal layer 120, and accordingly, the first metal layer 120 may not be removed in the process of removing the stopper layer S.

The process of removing the temporary layer T may be performed by delamination, is not limited thereto, may also be performed through different processes based on the material included in the temporary layer T such as being performed by the etching, and may use any process that may remove the material included in the temporary layer T without limitation. That is, different conditions may be implemented based on the material in the temporary layer T. The barrier layer 130 may be formed between the temporary layer T and the first insulating layer 111, and accordingly, the first insulating layer 111 may not be damaged in the process of removing the temporary layer T. In addition, in the process of forming the groove g, a portion of the temporary layer T and a portion of the barrier layer 130 may be removed, and the temporary layer T and the barrier layer 130 may thus be easily separated from each other.

Through the process of removing the temporary layer T, the protruding part 121 of the first metal layer 120 may protrude beyond the first insulating layer 111. That is, the protruding part 121 of the first metal layer 120 may function as a metal post.

Referring to FIG. 15, the manufacturing method of a printed circuit board may further include a process of forming a surface treatment layer 140 on the first metal layer 120. The surface treatment layer 140 may be formed in a region of the first metal layer 120 that is externally exposed, and formed on portions of the protruding part 121 of the first metal layer 120 and the groove g. The surface treatment layer 140 may be formed through the electroless plating and substitution plating, is not necessarily limited thereto, and use a different manufacturing method based on a structure of the surface treatment layer 140. In addition, the surface treatment layer may be formed through organic film coating when having an organic film structure including an organic material. In this way, the method of forming the surface treatment layer 140 may use any method of forming the surface treatment layer 140, which may be used by those skilled in the art, without particular limitation.

Referring to FIGS. 5 through 15, each drawing shows that the components are formed only on the lower side of the carrier board C. However, the printed circuit board having a symmetrical structure may be manufactured by performing the same process on the top of the carrier board C. In this case, two printed circuit boards having the same structure may be manufactured through one carrier board C. In addition, the method may not be limited thereto, and may manufacture the plurality of printed circuit boards by cutting the respective printed circuit boards after implementing the plurality of boards in the form of a strip board on one carrier board C.

As set forth above, the present disclosure may provide the printed circuit board that may be connected with the electronic component having the high-density microcircuit.

The present disclosure may also provide the printed circuit board having the microcircuit implementation structure that protrudes to the outermost side.

The present disclosure may also provide the printed circuit board having the improved reliability.

In addition, as described above in the description of the printed circuit board, the printed circuit board may further include its general configuration which may be freely added or omitted as long as this configuration does not change the technical spirit of the present disclosure.

In the present disclosure, the cross-sectional shape may be a cross-sectional shape of an object when the object is vertically cut or its cross-sectional shape when the object is viewed from a side. In addition, the planar shape may be a shape of an object when the object is horizontally cut, or its planar shape when the object is viewed from top or bottom.

In the present disclosure, the upper side, the upper portion, the upper surface, or the like refer to the direction toward the side where the electronic component may be mounted based on the cross section of the drawings for convenience, and the lower side, the lower portion, the lower surface, or the like refer to the opposite direction. However, these directions are defined for convenience of explanation, and the scope of the claims is not particularly limited by the directions defined as described above.

In the present disclosure, the connection between two components conceptually includes their indirect connection through an adhesive layer or the like as well as their direct connection. In addition, the expression, “electrically connected”, conceptually includes a physical connection and a physical disconnection. In addition, the term such as “first” or “second”, is used only to distinguish a component from another component, and may not limit the sequence or importance of the component. In some cases, a first component may be referred to as a second component without departing from the scope of the claims set forth herein. Similarly, a second component may also be referred to as a first component.

In the present disclosure, the expression, “substantially”, may be determined by including a process error, a positional deviation, an error in measurement, and the like that occur in the manufacturing process. In one or more aspects, the term “substantially” (“about,” “approximately,” etc.) may provide an industry-accepted tolerance for the corresponding term and/or relativity between items, such as a tolerance of ±1%, ±5%, or ±10% of the actual value stated, and other suitable tolerances. For example, being “substantially” vertical may include not only the case of being completely vertical, but also the case of being approximately vertical. In addition, being “substantially” coplanar may include not only the case of being completely on the same plane, but also the case of being approximately on the same plane. In addition, being “substantially” tapered may include not only the case of changing the width with a completely constant inclination, but also the case of roughly changing the width of one side and the width of the opposite side for the widths to be different from each other.

In the present disclosure, the same material may include the materials of the same type as well as exactly the same material. Therefore, and a specific composition ratio of the material may be slightly different from each other although their compositions are substantially the same as each other.

The expression, “an exemplary embodiment”, used herein does not refer to the same exemplary embodiment, and is provided to emphasize each particular feature different from that of another exemplary embodiment. However, the exemplary embodiments provided herein do not exclude being implemented in conjunction with the features of another exemplary embodiment. For example, one element described in a particular exemplary embodiment may be understood as a description related to another exemplary embodiment even if the element is not described in another exemplary embodiment, unless an opposite or contradictory description is provided therein.

The terms used herein are used only to describe an exemplary embodiment rather than limit the present disclosure. Here, the term of a singular number includes its plural number unless explicitly interpreted otherwise in the context.

While the example embodiments have been shown and described above, it will be apparent to those skilled in the art that modifications and variations could be made without departing from the scope of the present disclosure as defined by the appended claims.

What is claimed is:

1. A printed circuit board comprising:
a first insulating layer;
a first metal layer having a part protruding beyond the first insulating layer and another part buried in the first insulating layer; and
a barrier layer disposed on the first insulating layer,
wherein the barrier layer includes an inorganic oxide film.

2. The printed circuit board of claim 1, wherein the buried part of the first metal layer passes through upper and lower surfaces of the first insulating layer.

3. The printed circuit board of claim 1, further comprising:
a second insulating layer disposed below the first insulating layer;
a first wiring layer disposed on the second insulating layer; and
a first via layer passing through at least a portion of the second insulating layer to connect the first wiring layer and the first metal layer to each other.

4. The printed circuit board of claim 3, wherein the first insulating layer and the second insulating layer include insulating materials substantially the same as each other.

5. The printed circuit board of claim 1, wherein the barrier layer is disposed on at least a portion of the first insulating layer, and in contact with a side of the first metal layer.

6. The printed circuit board of claim 1, wherein the barrier layer is thinner than the first insulating layer.

7. The printed circuit board of claim 1, wherein the first metal layer includes a seed layer disposed on outside of the first metal layer and a plating layer disposed on the seed layer, and
the barrier layer is thinner than the seed layer.

8. The printed circuit board of claim 1, further comprising a surface treatment layer disposed on the first metal layer.

9. The printed circuit board of claim 8, wherein the surface treatment layer covers the part protruding beyond the first insulating layer.

10. A printed circuit board comprising:
a first insulating layer; and
a first metal layer having a protruding part protruding beyond the first insulating layer, a buried part buried in the first insulating layer, and a protrusion protruding outwards with respect to a side surface of the buried part and a side surface of the protruding part where the protrusion is in contact with the buried part and the protruding part.

11. The printed circuit board of claim 10, wherein the protrusion has a portion disposed on inside of the first insulating layer and another portion disposed on outside of the first insulating layer.

12. The printed circuit board of claim 10, further comprising:
a second insulating layer disposed below the first insulating layer; and
a first wiring layer disposed on the second insulating layer and including a first pad and a first pattern.

13. The printed circuit board of claim 12, wherein a width between both ends of the protrusion is narrower than a width of the first pad.

14. The printed circuit board of claim 10, wherein the first metal layer includes the protruding part, a seed layer extending along outside of the protrusion and the buried part, and a plating layer disposed on the seed layer.

15. The printed circuit board of claim 10, further comprising a surface treatment layer disposed on the first metal layer.

16. The printed circuit board of claim 15, wherein the surface treatment layer covers at least portions of the protruding part and the protrusion.

17. The printed circuit board of claim 10, wherein the buried part has a shape tapered upward.

18. The printed circuit board of claim 10, further comprising:
a barrier layer disposed on the first insulating layer,
wherein the barrier layer is in contact with the protrusion.

19. The printed circuit board of claim 10, wherein the protruding part, the buried part, and the protrusion are formed integrally with one another.

20. The printed circuit board of claim 10, wherein the protrusion includes one portion disposed at a level above one surface of the first insulating layer and another portion disposed at a level below the one surface of the first insulating layer.
